(19) United States
(12) Patent Application Publication
(10) Pub. No.: US 2007/0262380 A1
(43) Pub. Date: Nov. 15, 2007

(54) Semiconductor device and method for manufacturing semiconductor device

(75) Inventors: Juri Kato, Chino-shi (JP); Kei Kanemoto, Suwa-gun (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/796,802

(22) Filed: Apr. 30, 2007

(30) Foreign Application Priority Data
May 15, 2006 (JP) 2006-135650

(51) Int. Cl. H01L 27/12

(52) U.S. Cl. 257/347

(57) ABSTRACT

A semiconductor device comprises: a semiconductor substrate including a SOI region and a bulk region; a first element formed in the SOI region; a second element formed in the bulk region; a first element isolation layer including a trench structure; and a second element isolation layer including a LOCOS structure. The first element is separated from the second element by the first isolation layer and the second isolation layer.

### BACKGROUND OF THE INVENTION

1. Technical Field

Several aspects of the present invention relate to a semiconductor device and a method for manufacturing the semiconductor device. In particular, it relates to a technology in which a cross talk noise between a SOI region and a bulk region is reduced and crystal defects are eliminated.

2. Related Art

JPA 2005-354024 and “Separation by bonding Si Islands (SBSI) for LSI application”, by T. Sakai et al. in the Second international Si—Ge Technology and Device Meeting, Meeting Abstract, pp. 230-231, May 2004 disclose a method of selectively forming a SOI region in a semiconductor substrate, for example. The method forms a hybrid structure in which a device including a bulk structure (a bulk structured device) such as MOSFET, DRAM memories and bipolar transistors and a device including a SOI structure (a SOI structured device) are integrated in one substrate.

A semiconductor device having a hybrid structure, in which a bulk structured device and a SOI structured device are integrated in one substrate, however, has a problem in that a bulk structured device is influenced by a cross-talk noise from a SOI structured device and the vice versa, yielding unstable characteristics of the device. In particular, analogue elements, digital elements driven by an ultra low voltage are easily affected by a cross-talk noise. As a method of reducing a cross-talk noise, a deep groove (a trench) is formed between a bulk structured device and a SOI structured device and an insulating film is embedded into the trench, as isolating the bulk structured device from a SOI structured device each other.

In this method, however, when a solid insulating film, of which thermal expansion is different from that of a silicon substrate, is formed in a deep trench of the silicon substrate, thermal and mechanical stresses are applied to the silicon substrate at the time of process integration and mounting. If such stress is large, it yields crystal defects in active regions of a device (a SOI layer or silicon substrate), as lowering a yield of semiconductor devices and deteriorating reliability of devices. In particular, a SOI device has a smaller size compared to a bulk structured device and a smaller area ratio of active regions to element isolation regions. Hence, a stress is easily concentrated to an active region from a element isolation region, generating crystal defects in a SOI layer.

### SUMMARY

An advantage of the present invention provides a semiconductor device and a method for manufacturing the semiconductor device, in which a cross talk noise between a SOI region and a bulk region is reduced and crystal defects are eliminated.

According to a first aspect of the invention, a semiconductor device includes: a semiconductor substrate having a SOI region and a bulk region; a first element formed in the SOI region; a second element formed in the bulk region; a first element isolation layer having a trench structure; and a second element isolation layer having a LOCOS structure. The first element is separated from the second element by the first isolation layer and the second isolation layer.

Here, “the SOI region” means a region in which a single crystal semiconductor layer is (or was) formed on an insulating layer. As a material of a single crystal semiconductor layer, silicon is used for example. The “bulk region” means a region in which a SOI structure is not formed, namely, a element is (or was) directly formed in the semiconductor substrate without through a insulating layer.

According to the first aspect, a cross talk noise is effectively reduced in a region between the first element formed in the SOI region and the second element formed in the bulk region. For example, even when the first element formed in the SOI region is a low voltage-driven device and the second element formed in the bulk region is a high current-driven device, a noise from high voltage or high current driven devices to a low voltage-driven device can be drastically reduced, avoiding malfunction of devices.

Further, according to the first aspect of the invention, a cross talk noise can be reduced even if the trench structure of the first isolation layer is not deepened so much. Namely, the above first aspect can shallow the trench structure while reducing a cross talk noise, compared to the case in which the first element formed in the SOI region is isolated from the second element formed in the bulk region only by the trench structure.

If the trench structure is deep, a stress is increased. Hence shallowing the trench structure can reduce a stress generated in the neighbor of the interface between the SOI region and the bulk region, eliminating crystal defects in both the SOI region and the bulk region.

As a second aspect of the invention, the first isolation layer may be in abutment and integrated with the second isolation layer in the first aspect. This structure can constrain the area ratio of the element isolation region within the semiconductor substrate to the minimum necessary, as contributing to the downsizing of a chip.

According to a third aspect of the invention, a semiconductor device according to the first or the second aspect may further includes: a plurality of the first elements formed in the SOI region and a plurality of the second elements formed in the bulk region. A trench structured element isolation layer separates one of the first elements from others. A LOCOS structured element isolation layer separates one of the second elements from others.

In the aspect, a volume for an insulating film of the element isolation layer can be decreased, decreasing thermal and mechanical stress applied to a semiconductor substrate or SOI layer when process integrating or mounting. Further, the ratio of area for an element isolation region can be reduced in the SOI region and highly dense elements can be attained in the SOI region.

On the other hand, in the bulk region, the interface (Si/SiO₂ interface for example) between the semiconductor substrate and the LOCOS structure has a gentle slope. This structure relaxes the concentration of mechanical stress while improving the endurance against electrical field, comparing the trench structure, which has a sharp interface.

According to a fourth aspect of the invention, a method of manufacturing a semiconductor device that has a SOI region and a bulk region in a semiconductor substrate includes: forming a first element in the SOI region; forming a second element in the bulk region; forming a first element isolation layer including a trench structure; and forming a second element isolation layer including a LOCOS structure between the first element and the second element, wherein the first element is separated from the second element by the first element isolation layer and the second element isolation layer.

According to this aspect, a cross talk noise is effectively reduced in a region between the first element formed in the SOI region and the second element formed in the bulk region. This structure reduces a cross talk noise while making the trench structure shallow. Thus, it can reduces a stress yielded in the area close to the interface between the SOI region and the bulk region in the semiconductor substrate, avoiding the generation of crystal defects in both the SOI region and the bulk region.

According to the fifth aspect of the invention, the method of manufacturing a semiconductor device in the fourth aspect may further include: forming a first semiconductor layer on a semiconductor substrate in a SOI region; forming a second semiconductor layer on the first semiconductor layer; forming a first groove that penetrates through the second semiconductor layer and the first semiconductor layer and exposes the semiconductor substrate; forming an insulating layer within the first groove, the insulating layer supporting the second groove; forming a second groove that exposes the first semiconductor layer from the bottom of the second semiconductor layer supported by the insulating layer; forming a cavity portion between the semiconductor substrate and the second semiconductor layer by etching the first semiconductor layer via the second groove under a specific condition in which the first semiconductor layer is easily etched, compared to the second semiconductor layer; and embedding a insulating film in the cavity portion. The above method makes it possible to selectively form the SOI region on the bulk of the semiconductor substrate.

According to the sixth aspect of the invention, the method of manufacturing a semiconductor device in the fifth aspect may further include: forming a trench that isolates the first element when forming the first groove; and embedding the insulation film into the trench that isolates the first element when forming the insulation film in the first groove. The above method can shrink a process of manufacturing a semiconductor device, compared to the case when forming the first groove and the trench for isolating the first element separately.

According to the seventh aspect of the invention, in the method of manufacturing a semiconductor device in the sixth aspect, a part of the first groove may be used for forming a trench that isolates the first element. The above method can make a chip size of a semiconductor device small, compared to the case when forming the first groove and the trench for isolating the first element separately.

### BRIEF DESCRIPTION OF THE DRAWINGS

The invention will be described with reference to the accompanying drawings, wherein like numbers reference like elements.

FIG. 1 shows a cross section of a method of manufacturing a semiconductor device of an embodiment (first).

FIG. 2 shows a cross section of a method of manufacturing a semiconductor device of the embodiment (second).

FIG. 3 shows a cross section of a method of manufacturing a semiconductor device of the embodiment (third).

FIG. 4 shows a cross section of a method of manufacturing a semiconductor device of the embodiment (fourth.)

FIG. 5 shows a cross section of a method of manufacturing a semiconductor device of the embodiment (fifth.)

FIG. 6 shows a cross section of a method of manufacturing a semiconductor device of the embodiment (sixth.)

FIG. 7 shows a cross section of a method of manufacturing a semiconductor device of the embodiment (seventh.)

FIG. 8 shows a cross section of a method of manufacturing a semiconductor device of the embodiment (eighth.)

FIG. 9 shows a cross section of a method of manufacturing a semiconductor device of the embodiment (ninth.)

FIG. 10 is a plane view showing an example of forming a first trench groove h1.

FIG. 11 is a plane view showing an example of forming a second trench groove h2.

### DESCRIPTION OF EXEMPLARY EMBODIMENTS

Embodiments of the invention will now be described with reference to the accompanying drawings.

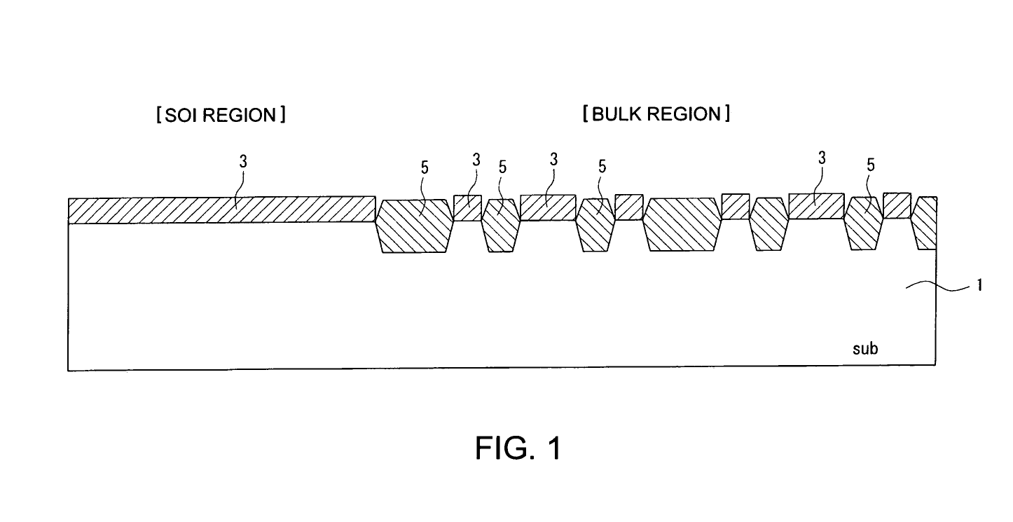

FIGS. 1 to 9 are sectional views showing a method for manufacturing a semiconductor device according to an embodiment of the invention.

In the embodiment, a low voltage driven device (LV-MOSFET) is formed in a SOI region and a high voltage driven device (HV-MOSFET) is formed in a bulk region. Then, specific element isolation layer is formed in a region between LV-MOSFET and HV-MOSFET.

As shown in FIG. 1, a single crystal semiconductor substrate (namely a bulk substrate) 1 is prepared. A material of the semiconductor substrate 1 is silicon for example. Next, the film 3 for preventing oxidization is formed on the semiconductor substrate 1. The film 3 is used as a mask when a LOCOS (local oxidization of silicon) film 5 is formed. The film 3 includes a silicon-oxidized film as a lower layer and silicon nitride film as an upper layer for example. The silicon oxidized film as a lower layer is formed by thermal oxidization and the silicon nitride film as an upper layer is formed by CVD for example.

Next, as shown in FIG. 1, the film 3 is patterned by a photolithography and etching technology. This patterning exposes only a region (an element isolation region) for forming the LOCOS film 5 in the bulk from the film 3. Then, the semiconductor substrate 1 is thermally oxidized, forming the LOCOS film 5 in the bulk region. The film 3 is removed thereafter.

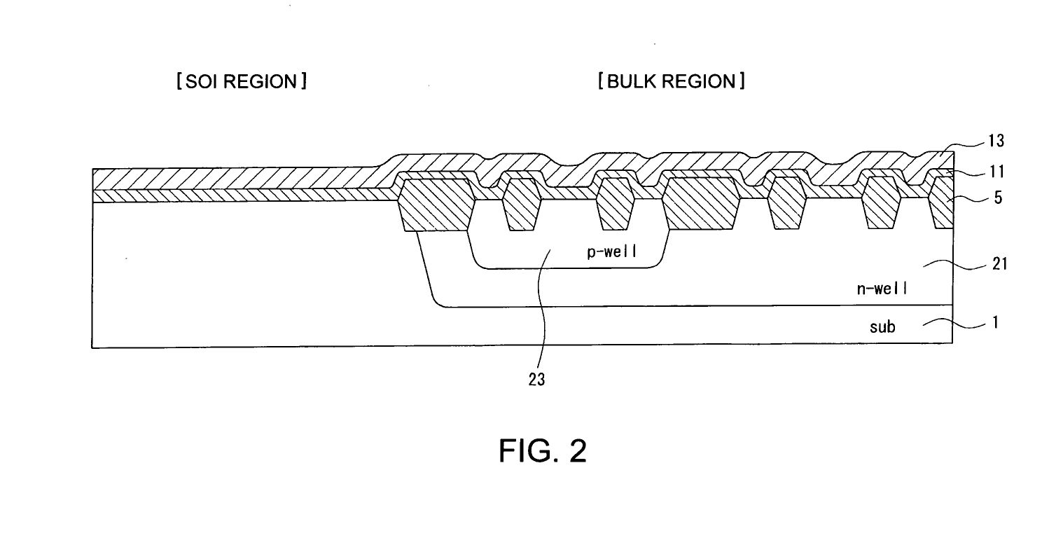

Next, as shown in FIG. 2, a silicon oxide film 11 is formed on a entire surface of the silicon substrate 1 for example and a silicon nitride film 13 is formed on it. The silicon oxidized film 11 and the silicon nitride film 13 are formed by CVD, for example.

Next, as shown in FIG. 2, n-type impurity is ion-injected into the bulk region of the semiconductor substrate by photolithography and ion injection technology. Then, a n-type well 21 is formed in the semiconductor substrate by annealing process (namely drive in) Next, p-type impurity is ion-injected into a n-type well of the bulk region of the semiconductor substrate by photo lithography and ion injection technology. Then, a p-type well 23 is formed in the semiconductor substrate 1 by annealing process (namely drive in) As n-type impurity, phosphor is used and as a p-type impurity, boron is used for example.

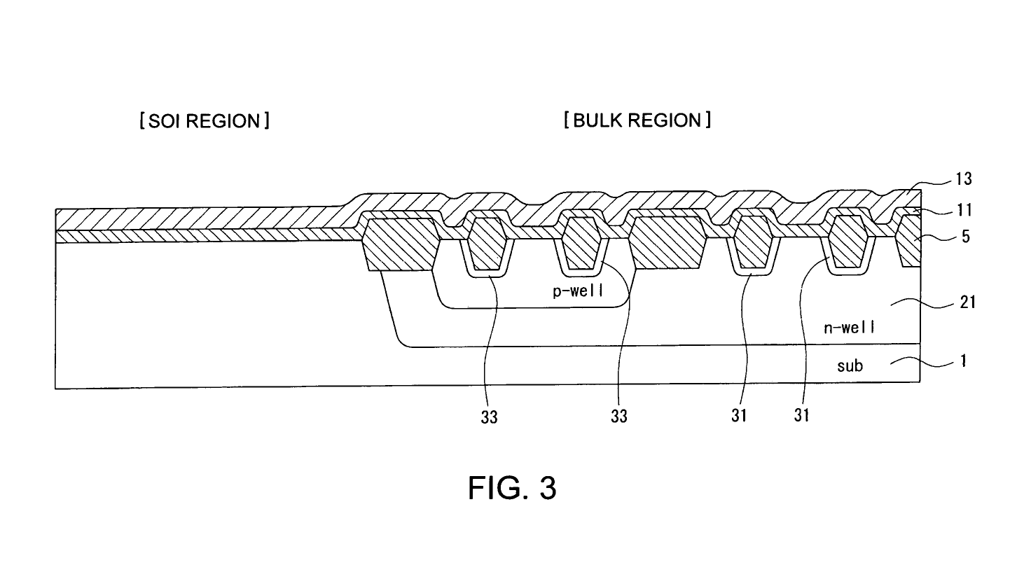

Next, as shown in FIG. 3, a source and a drain of a high voltage (HV) transistor are formed in the n-type well 21 and p-type well 23. Namely, first, n-type impurity is ion-injected into the p-type well 23 by photolithography and ion injection technology. Then, a n channel S/D 33 is formed in the p-type well 23 by an annealing process (namely drive in) to the semiconductor substrate 1. Next, p-type impurity is ion-injected into the n-type well 21 by photolithography and ion injection technology. Then, a p-type channel S/D 31 is formed in the n-type well 21 by an annealing process (namely drive in) to the semiconductor substrate 1.

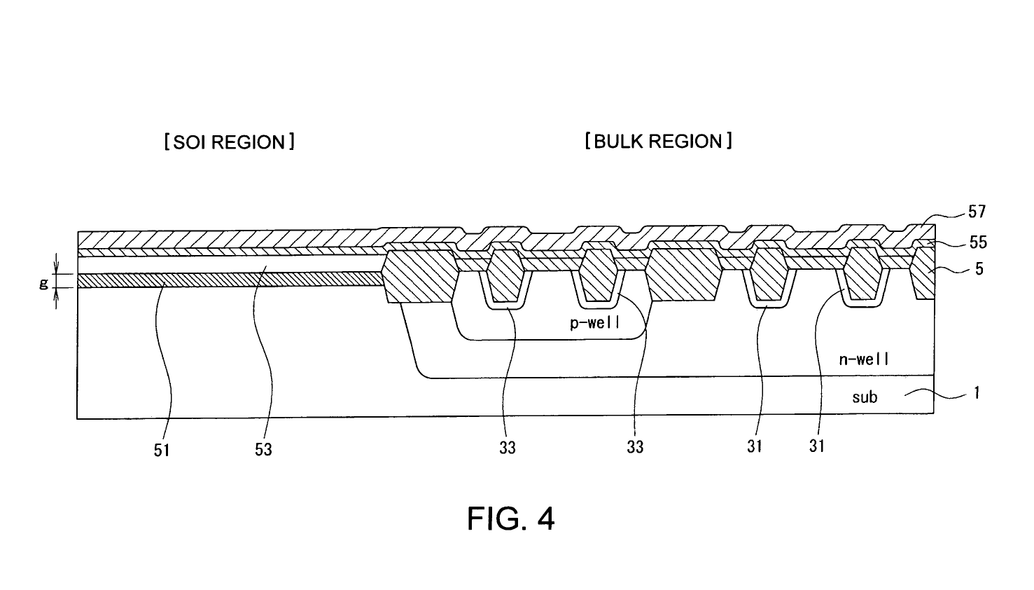

Next, as shown in FIG. 3, the silicon nitride film 13 is removed by etching and the silicon oxide film 11 is selectively removed, exposing the surface of the semiconductor substrate 1 in the SOI region. Here, the silicon oxide film 11 is left on the surface of the semiconductor substrate 1 in the bulk region. Further, the surface of the semiconductor substrate 1 in the SOI region is etched, forming a step 9 (see FIG. 4) between the SOI region and the bulk region on the surface of the semiconductor substrate 1. Then, a SOI structure is formed in the semiconductor substrate 1 by using the SBSI method. Namely, as shown in FIG. 4, a silicon germanium (Si—Ge) layer 51 and a silicon layer (Si) 53 are sequentially deposited only on the semiconductor substrate 1 in the SOI region. These silicon germanium (Si—Ge) layer 51 and silicon layer (Si) 53 are grown by a selective epitaxial growing method. The thickness of these silicon germanium (Si—Ge) layer 51 and silicon layer (Si) 53 are around 1 to 100 nm for example.

Next, as shown in FIG. 4, a base silicon oxide film 55 is formed on a entire surface of the silicon substrate 1 and a film 57 for preventing oxidization is formed on it. A silicon oxide film is used as the base silicon oxide film 55 and a silicon nitride film is used as the film 57 for preventing oxidization. The silicon oxidized film 55 and the silicon nitride film 57 are formed by CVD, for example. Here, when a silicon nitride film is used as the film 57, the film works as not only preventing oxidization of the Si layer 53, but as a stopper during a chemical mechanical polishing (CMP)

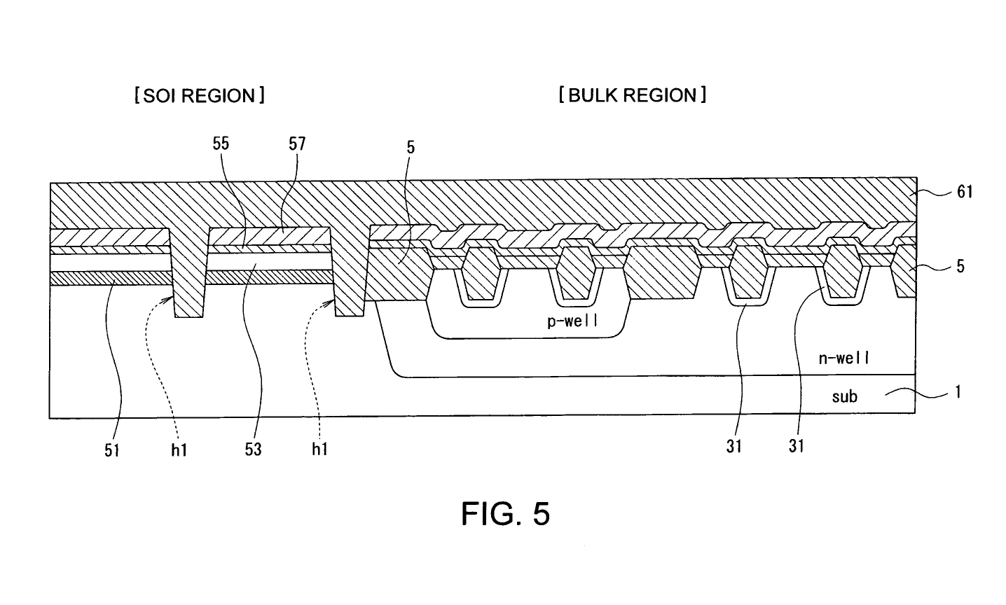

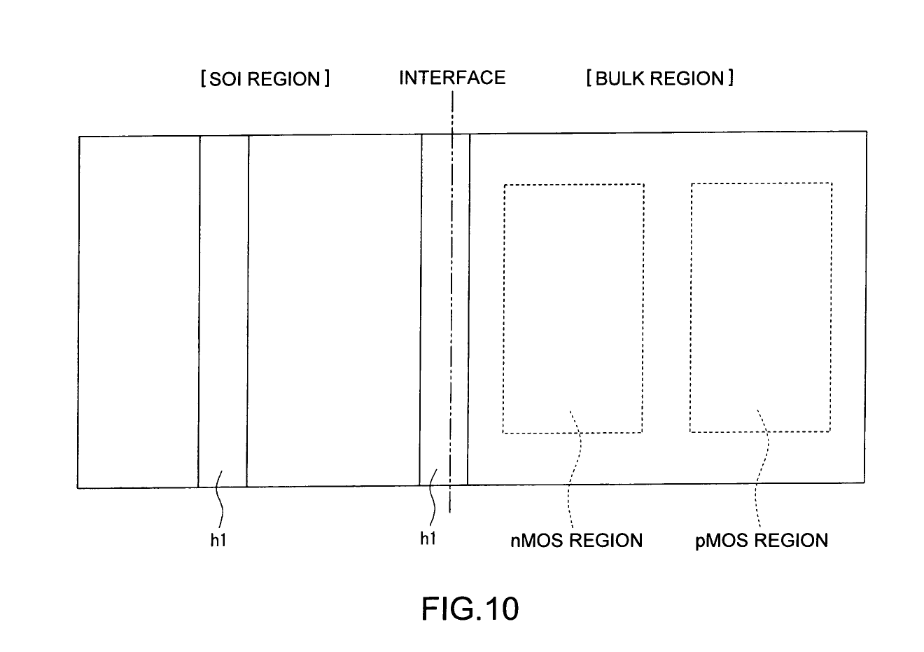

Next, as shown in FIG. 5, the film 57 for preventing oxidization, the base silicon oxide film 55, the Si layer 53 and the Si—Ge layer 51 are patterned so that the surface of the semiconductor substrate 1 is exposed. Then, the semiconductor substrate 1 is etched so that a first trench groove h1, of which the bottom is inside of the semiconductor substrate, is formed. As shown in FIG. 10, the LOCOS film located at the area of an interface between the SOI region and the bulk region is patterned so that a part of the trench groove h1 covers over the interface between the SOI region and the bulk region.

Next, a supporting member 61 is embedded into the trench groove h1 as covering over the entire surface of the substrate by CVD and the like. The supporting member 61 covering over the entire surface of the substrate must constrain bending of the Si layer 53 and support the Si layer 53 with holding flatness. In order to keep the mechanical strength of it, the thickness is favorably more than 400 nm. As the supporting member 61, an insulating member such as a silicon oxide film is used for example.

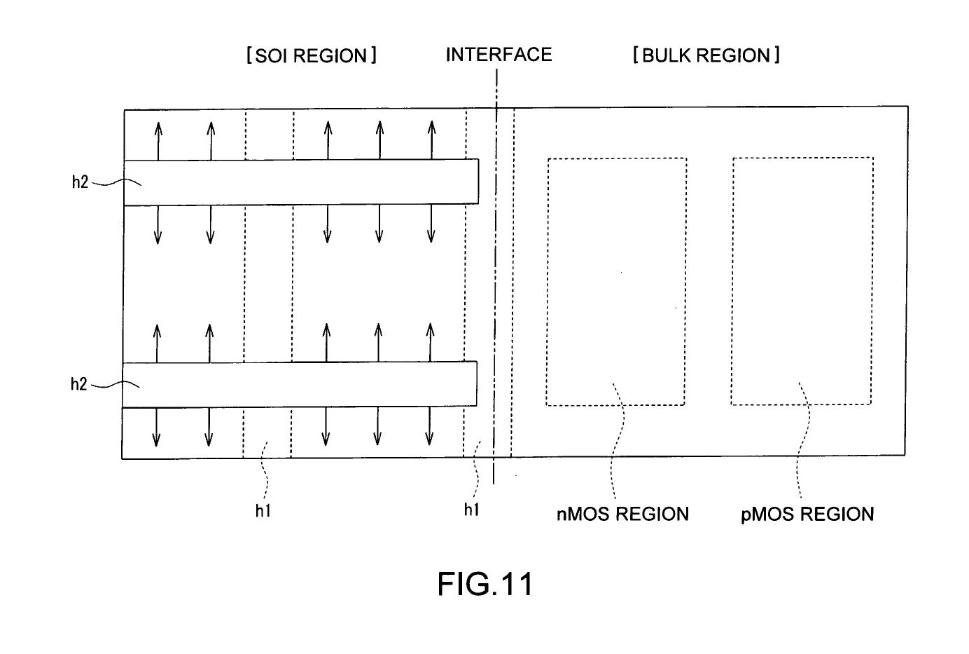

Next, the film 57 for preventing oxidization, the base silicon oxide film 55, the Si layer 53 and the Si—Ge layer 51 are patterned so that the surface of the semiconductor substrate 1 is exposed. Then, the semiconductor substrate 1 is etched so that a second trench groove h2 (see FIG. 11), of which the bottom is inside of the semiconductor substrate, is formed. Here, the location of the trench groove h2 (see FIG. 11) corresponds to a part of the element isolation region of the Si layer 53. Then, as shown in FIG. 11, the direction of the trench groove h2 is approximately perpendicular to the direction of the trench groove h1 in the plane view.

Next, an etching gas or liquid is contacted with the Si—Ge layer 51 (see FIG. 4) via the second trench groove h2 and the Si—Ge layer 51 is selectively removed so that a cavity portion H is formed between the semiconductor substrate 1 and the Si layer 53 (see FIG. 4.) The Si—Ge layer 51 is etched in parallel with the trench groove h2, indicated as the solid line in FIG. 11.

According to the embodiment, fluoride nitric acid is used as an etching liquid of the Si—Ge layer 51. Using the fluoride nitric acid constrains over etching of the semiconductor substrate 1 and the Si layer 53 and removes the Si—Ge layer 51. Here, the installation of the supporting member 61 in the trench groove h1 can support the Si layer 53 on the semiconductor substrate 1 even when removing the Si—Ge layer 51 in FIG. 5 generates a cavity.

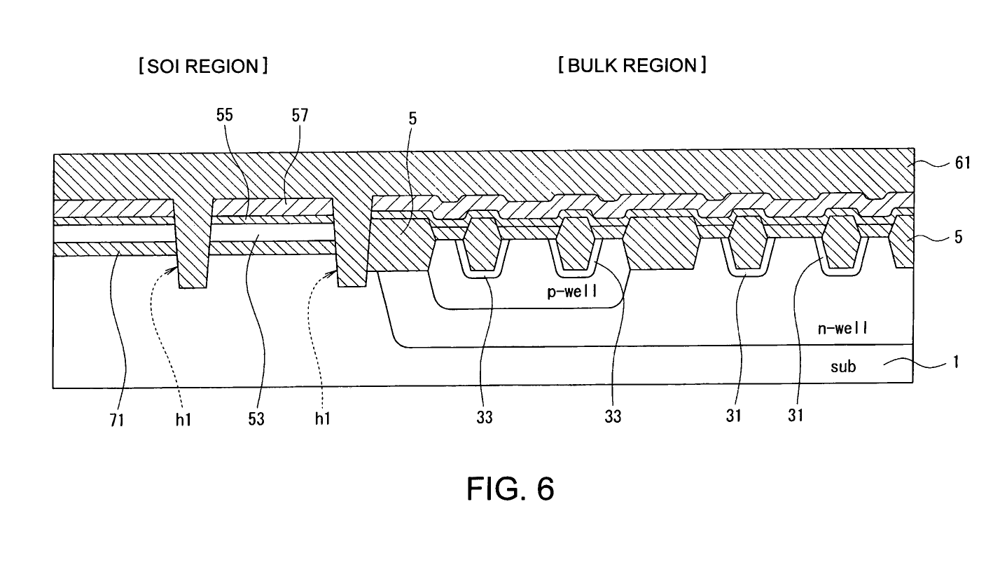

Then, an insulating film 71 is formed within the cavity portion by thermally oxidizing the semiconductor substrate 1 or processing it with CVD as shown in FIG. 6. Then the insulating film (not shown in the figure) is formed on the entire substrate and embedded within the second trench groove by CVD Forming the insulating film sets off the embedding of the insulating film 71 within the cavity portion. Here, the insulation film 71 is a silicon oxide film and an insulating film now shown in the figure formed by CVD and others is a silicon oxide film or a silicon nitride film for example.

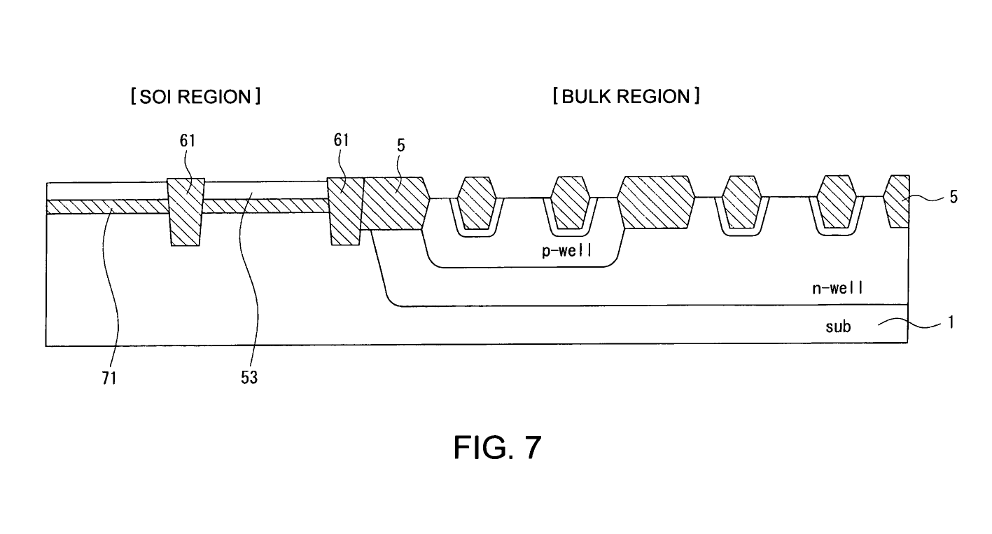

Next, in FIG. 6, the upper surface of the semiconductor substrate 1 is planarized by CMP and the insulation film not shown in the figure and the supporting member 61 are removed from the surface of the film 57 for preventing oxidization. As described above, if the film 57 for preventing oxidization is a silicon nitride film, the film 57 works as a stopper layer against a planarization process with CMP. Then, the film 57 for preventing oxidization, the base oxide film 55 and the silicon oxide film 11 are etched and removed as shown in FIG. 7. When the film 57 for preventing oxidization is a silicon nitride film, thermal phosphoric acid is used as an etching liquid. When the base oxide film 55 is a silicon oxide film, diluted fluorinated acid is used as a etching liquid. This processing exposes the surface of the Si layer 53 and the surface of the semiconductor substrate 1 in the bulk region.

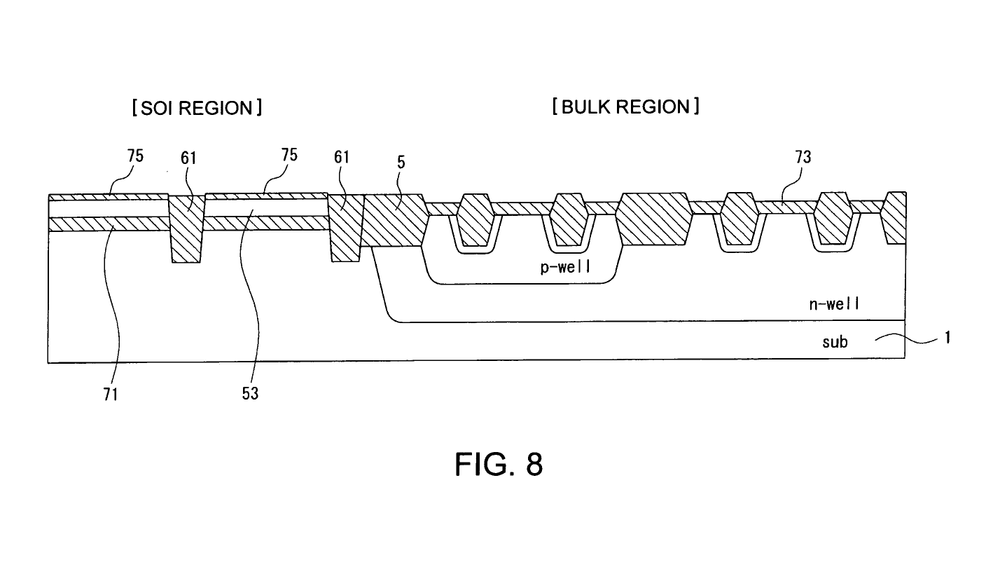

Next, as shown in FIG. 8, the semiconductor substrate 1 is thermally oxidized, forming the thick gate insulation layer 73 on the surface of the Si layer 53 and the surface of the semiconductor substrate 1 in the bulk region. Next, the thick gate insulation layer 73 formed only in the SOI region is removed by a photolithography and etching technology, exposing the surface of the Si layer. Then, a resist pattern is removed and the device is cleaned. Next, the semiconductor substrate 1 is thermally oxidized again and the thin gate insulating film 75 is formed on the Si layer 53 in the SOI region.

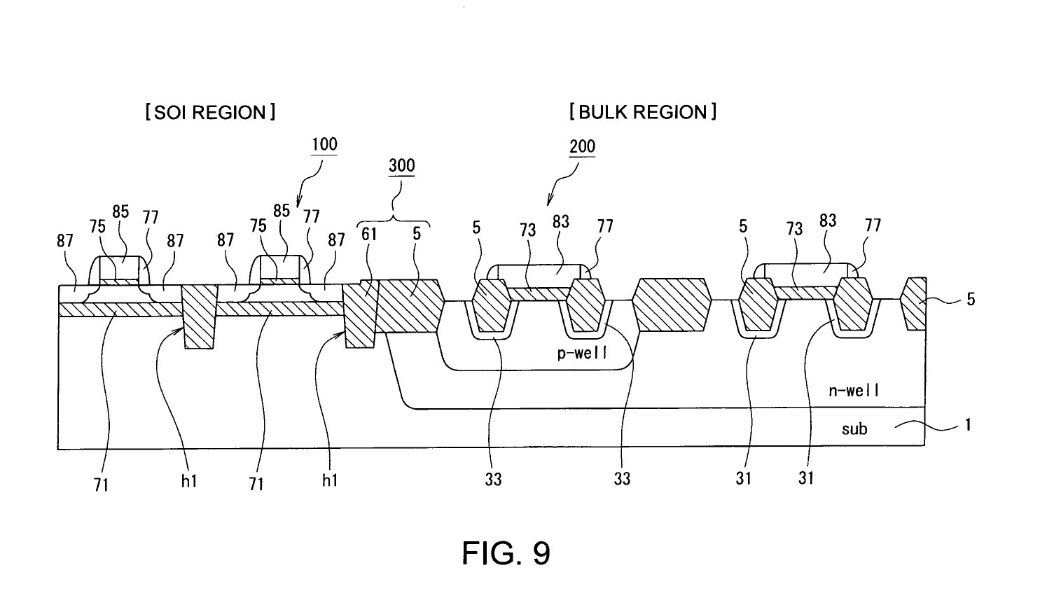

Then, a poly silicon layer is formed by CVD or the like on the semiconductor substrate 1 on which the gate insulating films 73 and 75 are formed. Further, the poly silicon layer is patterned by photolithography and a etching technology, forming a gate electrode 83 on the thick gate insulating film 57 in the bulk region as shown in FIG. 9 and a gate electrode 85 on the thin gate insulating film 75 in the SOI region.

Next, a LDD layer is formed the Si layer 53 on both sides of the gate electrode 85 by photolithography and ion injection technology. Then, an insulating layer is formed on the entire surface of the semiconductor substrate 1 by CVD or the like and etched back by anisotropic etching such as RIE, forming a side wall 77 on both sides of the gate electrodes 83 and 85.

Further, impurities such as, P and B are ion-injected into the Si layer 53 by a photolithography and ion injection technology, forming a source and a drain layers (S/D) 87 as a highly concentrated impurities layers in the Si layer 53, which are located on both sides of the side wall 77. At this time, the upper area of the S/D 31 and 33 in the bulk region is covered by a photo resist, preventing impurities from entering into the S/D 31 and 33. Consequently, a semiconductor device of a hybrid structure including a low voltage driven device (LV MSOFET) in the SOI region and a high voltage or high current driven device (HV-MOSFET) is completed.

According to the embodiment, an element isolation layer 300 separates a LV MSOFET 100 formed in the SOI region from a HV-MOSFET 200 formed in the bulk region. Further, the SOI side of the element isolation layer 300 has a trench structure (namely the supporting member 61 embedded in the trench groove h1) and the bulk side of it has a LOCOS structure (namely the LOCOS film 5.) This structure effectively reduces a cross talk between the LV-MSOFET100 formed in the SOI region from the HV-MOSFET 200 formed in the bulk region and reduces a noise from the HV-MOSFET 200 to the LV-MSOFET100, preventing the device from malfunctioning.

Further, according to the embodiment, a cross talk noise can be reduced even if the trench structure of the SOI side of the element isolation layer 300 is not deepened so much. Thus, it can reduces a stress yielded in the area close to the interface between the SOI region in the semiconductor substrate and the bulk region, avoiding the generation of crystal defects in both the SOI region and the bulk region.

Further, as shown in FIG. 9, in the embodiment, the element isolation structure at the side of bulk region of the interface between the SOI region and the bulk region and within in the bulk region constitutes only the LOCOS structure, and the interface of SiO₂/Si has a gentle slope. This structure relaxes a stress concentration and does not yield crystal defects in the semiconductor substrate in the bulk region, attaining favorable electrical characteristics. On the other hand, the element isolation structure within the SOI region has only a trench structure. The trench groove h1 has the same depth of the insulating film (namely a Box layer) 71 or more than the depth of the Box layer 71. This structure avoids stress concentration at the bottom of the trench groove h1 in the Si layer 53 (namely the SOI layer), offering the SOI layer without crystal defects. Further, this structure avoids yielding crystal defects for both the SOI layer in the SOI region and the semiconductor substrate in the bulk region, highly contributing to the improvement of the yield of a semiconductor device and its reliability.

Further, according to the embodiment, a part of the first trench groove h1 also works as a trench in the element isolation layer 300 of the SOI region side. Namely, when the first trench groove h1 is formed, a trench in the element isolation layer 300 of the SOI region side is also formed. Hence, a semiconductor device can be downsized and manufacturing process of it can be shortened.

In the embodiment, the element isolation layer 300, which is formed as the integration of the trench structure with the LOCOS structure, is placed between the LV-MSOFET100 formed in the SOI region and the HV-MOSFET 200 formed in the bulk region. The integration of the trench structure with the LOCOS structure can constrain the minimum necessity of the ratio of area of the element isolation layer to the area of the semiconductor substrate 1. On the other hand, the embodiment does not necessarily require such integration of the trench structure with the LOCOS structure. The trench structure may be separated form the LOCOS structure while it is close to the LOCOS structure. Even in such structure, the embodiment can reduce the cross talk between the SOI region and the bulk region and prevent the generation of crystal defects in the SOI layer and the bulk region.

In the embodiment, the LV-MOSFET 100 corresponds to a first element in the invention and the HV-MOSFET 100 corresponds to a second element in the invention. Further, the trench structure of the element isolation layer 300 at the side of the SOI region corresponds to a first element isolation layer in the invention and the LOCOS structure of the element isolation layer 300 at the side of the bulk region corresponds to a second element isolation layer in the invention. Further, the Si—Ge layer 51 corresponds to a first semiconductor layer and the Si layer 53 corresponds to a second semiconductor layer in the invention. Further, the trench groove h1 corresponds to a first groove and the trench groove h2 corresponds to a second groove. The supporting member 61 corresponds to a insulating layer supporting the second semiconductor layer in the invention.

What is claimed is:

1. A semiconductor device comprising:
a semiconductor substrate including a SOI region and a bulk region;
a first element formed in the SOI region;
a second element formed in the bulk region;
a first element isolation layer including a trench structure; and
a second element isolation layer including a LOCOS structure,
wherein the first element is separated from the second element by the first isolation layer and the second isolation layer.

2. The semiconductor device according to claim 1, wherein the first isolation layer is in abutment and integrated with the second isolation layer.

3. The semiconductor device according to claim 1, further comprising a plurality of the first elements formed in the SOI region; a plurality of the second elements formed in the bulk region,
wherein one of a plurality of the first elements is separated from other of the first elements only by the first element isolation layer including a trench structure, and one of a plurality of the second elements is separated from other of the second elements only by the second element isolation layer including a LOCS structure.

4. A method of manufacturing semiconductor device comprising:
forming a semiconductor substrate including a SOI region and a bulk region;
forming a first element in the SOI region;
forming a second element in the bulk region;
forming a first element isolation layer including a trench structure; and
forming a second element isolation layer including a LOCOS structure,
wherein the first element is separated from the second element by the first isolation layer and the second isolation layer.

5. The method of a semiconductor device according to claim 4, further comprising:
forming a first semiconductor layer on a semiconductor substrate in a SOI region;
forming a second semiconductor layer on the first semiconductor layer;
forming a first groove that penetrates through the second semiconductor layer and the first semiconductor layer and exposes the semiconductor substrate;
forming an insulating layer within the first groove, the insulating layer supporting the second groove;
forming a second groove that exposes the first semiconductor layer from the bottom of the second semiconductor layer supported by the insulating layer; forming a cavity portion between the semiconductor substrate and the second semiconductor layer by etching the first semiconductor layer via the second groove under a specific condition in which the first semiconductor layer is easily etched, compared to the second semiconductor layer; and
embedding a insulating film in the cavity portion.

6. The method of a semiconductor device according to claim 5, further comprising:
forming a trench that isolates the first element when forming the first groove; and
embedding the insulation film into the trench that isolates the first element when forming the insulation film in the first groove.

7. The method of a semiconductor device according to claim 6, wherein a part of the first groove is used for forming a trench that isolates the first element.
